(19) United States
(12) Patent Application Publication
(10) Pub. No.: US 2019/0027627 A1
(43) Pub. Date: Jan. 24, 2019

(54) SOLAR PHOTOVOLTAIC MODULE

(71) Applicant: INDUSTRIAL TECHNOLOGY RESEARCH INSTITUTE, Hsinchu (TW)

(72) Inventors: Wen-Kuei Lee, Puyan Township (TW); Mei-Hsiu Lin, Zhunan Township (TW); Cheng-Yu Peng, Taoyuan City (TW)

(21) Appl. No.: 15/826,002

(22) Filed: Nov. 29, 2017

(30) Foreign Application Priority Data
Jul. 20, 2017 (TW) 106124385

(51) Int. Cl. H01L 31/048; H01L 31/05

(52) U.S. Cl. CPC H01L 31/0481; H01L 31/0508

(57) ABSTRACT

A solar photovoltaic module including a solar cell, a first package layer and a second package layer is provided. The solar cell has a first surface and a second surface opposite to the first surface. The first package layer is formed on the first surface. The second package layer is formed on the second surface. The first package layer and the second package layer are made of different crosslinked materials, and a difference between the crosslink density of the first package layer and the crosslink density of the second package layer is equal to or less than 15%.

This application claims the benefit of Taiwan application Serial No. 106124385, filed Jul. 20, 2017, the subject matter of which is incorporated herein by reference.

### BACKGROUND OF THE INVENTION

### Field of the Invention

The invention relates in general to a solar photovoltaic module, and more particularly to a solar photovoltaic module with heterogeneous packaging and crosslink densities of materials.

### Description of the Related Art

Conventional solar photovoltaic module includes a solar cell. To package the solar cell and achieve an excellent coverage, normally the two sides of the solar cell are covered with homogeneous materials. However, the use of homogeneous materials limit the application of the packaging materials. For example, when the packaging materials are very expensive or have poor properties, the solar photovoltaic module would become even more expensive or have even poorer properties if both sides of the solar cell are covered with homogeneous materials.

### SUMMARY OF THE INVENTION

According to one embodiment of the invention, a solar photovoltaic module including a solar cell, a first package layer and a second package layer is provided. The solar cell has a first surface and a second surface opposite to the first surface. The first package layer is formed on the first surface. The second package layer is formed on the second surface. The first package layer and the second package layer are made of different crosslinked materials, and a difference between the crosslink density of the first package layer and the crosslink density of the second package layer is equal to or less than 15%.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a cross-sectional view of a solar photovoltaic module according to an embodiment of the invention.

FIG. 2 is a manufacturing process diagram of the solar photovoltaic module of FIG. 1.

### DETAILED DESCRIPTION OF THE INVENTION

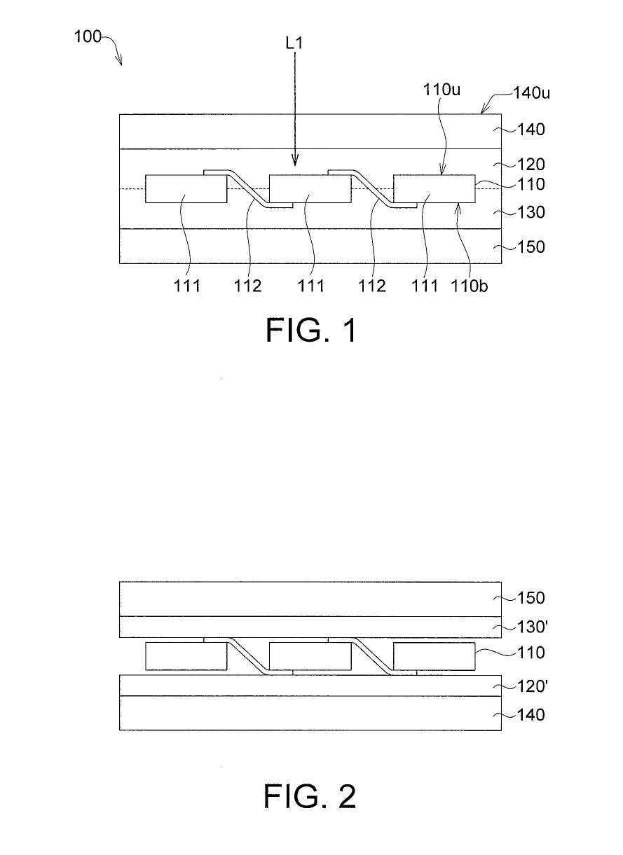

Referring to FIG. 1, a cross-sectional view of a solar photovoltaic module 100 according to an embodiment of the invention. The solar photovoltaic module 100 includes a solar cell 110, a first package layer 120, a second package layer 130, a translucent layer 140 and a back plate 150.

The back plate 150, the second package layer 130, the solar cell 110, the first package layer 120 and the translucent layer 140 are sequentially stacked bottom up in order. The solar cell 110 includes a number of electrically connected cell units 111. Two adjacent cell units 111 can be electrically connected by a wire 112, and the cell units 111 are series connected.

The solar cell 110 has a first surface 110u and a second surface 110b opposite to the first surface 110u. The first package layer 120 is formed on the first surface 110u. The second package layer 130 is formed on the second surface 110b. The first package layer 120 and the second package layer 130 contact each other and seal the solar cell 110. As indicated in FIG. 1, the dotted line between the first package layer 120 and the second package layer 130 indicates a close contact between the first package layer 120 and the second package layer 130. In an actual product, the cross section may or may not have an obvious contact interface.

The translucent layer 140 can be made of translucent glass. The translucent layer 140 has an incident surface 140u via which an external solar light L1 enters the solar photovoltaic module 100. The first surface 110u faces the incident surface 140u, such that the first package layer 120 formed on the first surface 110u is located on the incident surface 140u of the solar photovoltaic module 100. The insulation resistance of the first package layer 120 located on the incident side is larger than the insulation resistance of the second package layer 130 located on the back side, such that the weatherability of the solar photovoltaic module 100 is enhanced. Details of the said design can be obtained with reference to Table 4.

Besides, the first package layer 120 and the second package layer 130 can be made of polyolefin, ethylene vinyl acetate (EVA) or other suitable materials. In the present embodiment, the first package layer 120 and the second package layer 130 are made of different crosslinked materials. For example, the first package layer 120 is formed of a polyolefin layer, and the second package layer 130 is formed of an ethylene vinyl acetate layer. The price of polyolefin is higher than the price of vinyl acetate copolymer. Unlike the solar cell whose two opposite sides are both formed of a polyolefin layer, only one side of the solar photovoltaic module 100 of the embodiment of the invention is formed of a polyolefin layer, and therefore the overall price can be lowered.

Since the first package layer 120 and the second package layer 130 are made of different crosslinked materials, the crosslink density of the first package layer 120 and the crosslink density of the second package layer 130 are different. In the present embodiment, a difference between the crosslink density of the first package layer 120 and the crosslink density of the second package layer 130 is equal to or less than 15%, such that an expected coverage can be obtained.

Refer to Table 1-1 and Table 1-2. In the category, “0” represents the polyolefin layer (such as Model: F⋅RST® TF4 of the Hangzhou First Applied Material Co., Ltd.); “E” represents the EVA layer; “EE type” represents the solar photovoltaic module in which two opposite sides of the solar cell both are formed of the EVA layer; “OO type” represents the solar photovoltaic module in which two opposite sides of the solar cell both are formed of the polyolefin layer; and “OE type” represents the structure of the solar photovoltaic module 100 of the invention. Before the potential induced degradation (PID) test in accordance with the IEC 62804 standard is performed, the EE type, the OO type and the OE type solar photovoltaic modules do not have significant difference in terms of maximum power (Pmax) and fill factor (FF). However, after the PID test is performed, the maximum power and the fill factor of the OE type solar photovoltaic module are superior to that of the EE type solar photovoltaic module, but are close or not inferior to that of the OO type solar photovoltaic module. The test results show that the solar photovoltaic module 100 of the embodiment of the invention can provide expected weatherability. In other words, the weatherability of the solar photovoltaic module 100 of the embodiment of the invention using one polyolefin layer only is close to or not inferior to that of OO type solar photovoltaic module.

TABLE 1-1

| | Test | | | | | |
|---|---|---|---|---|---|---|
| | | | After 96 Hours | | After 192 Hours | |
| | Before PID Test | | of PID Test | | of PID Test | |
| | Pmax | FF | Pmax | FF | Pmax | FF |
| Category | (W) | (%) | (W) | (%) | (W) | (%) |
| EE type | 47.833 | 73.216 | 47.365 | 72.845 | 45.333 | 69.619 |
| OE type | 48.488 | 72.599 | 48.375 | 72.924 | 46.442 | 69.809 |
| OO type | 48.372 | 72.850 | 47.936 | 72.580 | 47.199 | 71.380 |

TABLE 1-2

| | Test | | | |
|---|---|---|---|---|
| | After 288 Hours of PID Test | | After 348 Hours of PID Test | |
| Category | Pmax (W) | FF (%) | Pmax (W) | FF (%) |
| EE type | 44.859 | 68.892 | 43.279 | 66.595 |
| OE type | 45.334 | 68.371 | 45.912 | 69.265 |
| OO type | 46.606 | 70.594 | 45.768 | 69.428 |

Besides, the PID tests of Table 1-1 and Table 1-2 are performed under the testing conditions of the high voltage bias being 1000V, the testing temperature being 85° C. and the humidity being 85% RH. After the test is performed over a period of time, a volt-ampere characteristic curve of the output power is obtained by an A class flash simulator under the STC conditions.

As indicated in Table 2, an insulation resistance test and a wet leakage current test are performed to the EE type, the OO type and the OE type solar photovoltaic modules before and after the PID test in accordance with the IEC 61215 standard is performed. Table 2 shows that after the PID test is performed, the EE type solar photovoltaic module has significant decay in insulation resistance and wet leakage current; the OO type and the OE type solar photovoltaic modules can resist both 96 hours and 192 hours of PID test, and therefore significantly have superior weatherability.

TABLE 2

| | Test | | | | | |
|---|---|---|---|---|---|---|
| | | | After 96 Hours | | After 192 Hours | |
| | Before PID Test | | of PID Test | | of PID Test | |
| | Insu- | Wet | Insu- | Wet | Insu- | Wet |
| | lation | Leakage | lation | Leakage | lation | Leakage |
| Category | (ΩM) | (ΩM) | (ΩM) | (ΩM) | (ΩM) | (ΩM) |
| EE type | >9999 | 2030 | 2151 | 1528 | 3432 | 355 |
| OE type | >9999 | 7458 | >9999 | >9999 | 6737 | 418 |
| OO type | >9999 | >9999 | >9999 | 9889 | >9999 | 3910 |

As indicated in Table 3-1 and Table 3-2, an insulation resistance test and a wet leakage current test are performed to the EO type and the OE type solar photovoltaic modules before and after PID test in accordance with the IEC 62804 standard is performed. The PID test is performed under the testing conditions of the high voltage bias being 1000V, the testing temperature being 85° C. and the humidity being 85% RH. After the test is performed over a period of time, a volt-ampere characteristic curve of the output power is obtained by an A class flash simulator under the STC conditions. The EO type solar photovoltaic module can be obtained by swapping the positions of the first package layer 120 and the second package layer 130 of the solar photovoltaic module 100, wherein “Voc” represents open-loop voltage (the unit is volt (V)); “Isc” represents short-circuiting current (the unit is ampere (A)); “Pmax” represents the maximum power (the unit is Watt (W)).

Table 3-1 and Table 3-2 show that in comparison to the EO type solar photovoltaic module, the OE type solar photovoltaic module (that is, the solar photovoltaic module 100) has superior weatherability. For example, after 288 hours of PID test, the OE type solar photovoltaic module still higher fill factor than the EO type solar photovoltaic module.

TABLE 3-1

| | Test | | | | | | | |
|---|---|---|---|---|---|---|---|---|
| | | | | | After 96 Hours | | | |
| | Before PID Test | | | | of PID Test | | | |
| Cate- | Voc | Isc | Pmax | FF | Voc | Isc | Pmax | FF |
| gory | (V) | (A) | (W) | (%) | (V) | (A) | (W) | (%) |
| EO | 7.655 | 8.953 | 51.355 | 74.927 | 7.613 | 8.933 | 50.126 | 73.710 |
| type | | | | | | | | |
| OE | 7.646 | 8.937 | 51.138 | 74.835 | 7.649 | 8.947 | 50.955 | 74.456 |
| type | | | | | | | | |

TABLE 3-2

| | Test | | | | | | | |
|---|---|---|---|---|---|---|---|---|
| | After 192 Hours | | | | After Hours | | | |
| | of PID Test | | | | of PID test 288 | | | |
| Cate- | Voc | Isc | Pmax | FF | Voc | Isc | Pmax | FF |
| gory | (V) | (A) | (W) | (%) | (V) | (A) | (W) | (%) |
| EO | 7.622 | 8.943 | 49.820 | 73.083 | 7.631 | 8.945 | 50.199 | 73.536 |
| type | | | | | | | | |
| OE | 7.650 | 8.942 | 50.461 | 73.768 | 7.651 | 8.935 | 50.721 | 74.187 |
| type | | | | | | | | |

Besides, the decay rate of the fill factor of the OE type solar photovoltaic module is slower than that of the EO type solar photovoltaic module. After the PID test is performed for 96 hours, the decay rate of the fill factor of the EO type solar photovoltaic module is about 1.6% (decays to 73.710% from 74.927%) and the decay rate of the fill factor of the OE type solar photovoltaic module is only about 0.5% (decays to 74.456% from 74.835%) in comparison to the fill factor before the PID test is performed. After the PID test is performed for 288 hours, the decay rate of the fill factor of the EO type solar photovoltaic module is about 1.9% (decays to 73.536% from 74.927%), and the decay rate of the fill factor of the OE type solar photovoltaic module is only about 0.9% (decays to 74.187% from 74.835%) in comparison to the fill factor before the PID test is performed. The test results show that the OE type solar photovoltaic module has superior weatherability.

As indicated in Table 4, an insulation resistance test and a wet leakage current test are performed to the OE type and the EO type solar photovoltaic modules before and after the PID test in accordance with the IEC 61215 standard is performed. In table 4, “Rs” represents series resistance. In the OE type solar photovoltaic module (that is, the solar photovoltaic module 100), the insulation resistance of the first package layer 120 located on the incident surface 140u is larger than the insulation resistance of the second package layer 130 located on the back side. Thus, the OE type solar photovoltaic module is superior to the EO type solar photovoltaic module in terms of fill factor, insulation resistance, and wet leakage current, and has superior weatherability.

TABLE 4

| | Test | | | | |
|---|---|---|---|---|---|
| | | | | | Wet |
| | | | | Insulation | Leakage |
| Category | PID Test | FF (%) | Rs (Ω) | (MΩ) | (MΩ) |
| OE type | Before test | 74.835 | 0.115 | >9999 | >9999 |
| | After 96 Hours | 74.456 | 0.119 | >9999 | 3313 |
| | of Test | | | | |
| | After 288 Hours | 74.187 | 0.120 | >9999 | 7334 |
| | of Test | | | | |
| EO type | Before Test | 74.409 | 0.121 | >9999 | 2859 |
| | After 96 Hours | 74.035 | 0.123 | 1834 | 1534 |
| | of Test | | | | |
| | After 288 Hours | 73.836 | 0.127 | 1520 | 1246 |
| | of Test | | | | |

Table 5-1 and Table 5-2 show the performance of the maximum power and the fill factor of the OE type solar photovoltaic module under the difference between crosslink densities. The difference between crosslink densities is such as the difference between the crosslink density of polyolefin and the crosslink density of EVA. As indicated in Table 5-1, after the PID test is performed for 96 hours, as the difference between crosslink densities increases, the decay in the maximum power and the decay in the fill factor tend to increase as well. Let the 96 hours of test be taken for example. When the difference between crosslink densities is smaller than 20%, the decay rate of the maximum power and the decay rate the fill factor both are smaller than 3%. As indicate in Table 5-2, after the PID test is performed for 192 hours, the decay rate of the maximum power and the decay rate of the fill factor are even larger than that obtained from the 96 hours of PID test. Let the 192 hours of test be taken for example. When the difference between crosslink densities is smaller than 15%, the decay rate of the maximum power is smaller than 5%, and the decay rate of the fill factor is smaller than 4%.

TABLE 5-1

| | Test | | | | | |
|---|---|---|---|---|---|---|
| Difference | | | After 96 Hours | | | |
| between | | | of PID Test | | | |
| Crosslink | Before PID Test | | | | Pmax | FF |
| Densities of | Pmax | FF | Pmax | FF | Decay | Decay |
| OE Type | (W) | (%) | (W) | (%) | Rate(%) | Rate(%) |
| 5% | 48.678 | 73.370 | 48.589 | 73.202 | 0.183 | 0.229 |
| 10% | 48.939 | 73.467 | 48.688 | 72.733 | 0.513 | 0.999 |
| 15% | 48.488 | 72.599 | 48.375 | 72.924 | 0.233 | −0.448 |
| 20% | 48.574 | 72.941 | 47.257 | 70.911 | 2.711 | 2.783 |
| 25% | 49.066 | 73.788 | 45.380 | 66.240 | 7.512 | 10.229 |

TABLE 5-2

| Difference | |
|---|---|
| between | Test |
| Crosslink | After 192 Hours of PID Test |

| Densities of | Pmax | FF | Pmax Decay | FF Decay |
|---|---|---|---|---|
| OE Type | (W) | (%) | Rate (%) | Rate (%) |
| 5% | 48.299 | 73.209 | 0.779 | 0.219 |
| 10% | 48.000 | 72.246 | 1.919 | 1.662 |
| 15% | 46.442 | 69.809 | 4.220 | 3.843 |
| 20% | 45.570 | 68.787 | 6.184 | 5.695 |
| 25% | 43.540 | 68.680 | 11.262 | 6.923 |

Referring to FIG. 2, a manufacturing process diagram of the solar photovoltaic module 100 of FIG. 1 is shown. In the lamination process, the translucent layer 140, the first packaging material 120′ (solid layer), the solar cell 110, the second packaging material 130′ (solid layer) and the back plate 150 are sequentially stacked bottom up on a lamination equipment (not illustrated). The first packaging material 120′ and the second packaging material 130′ can be formed of polyolefin, ethylene vinyl acetate or other suitable materials. In the present embodiment, the first package layer 120 and the second package layer 130 are made of different crosslinked materials. For example, the first packaging material 120′ is formed of a polyolefin layer, and the second packaging material 130′ is formed of an ethylene vinyl acetate layer. Then, under the process conditions of the lamination temperature being about 150° C. and the pressure inside the cavity being about 0.01 torr, the translucent layer 140, the first packaging material 120′, the solar cell 110, the second packaging material 130′ and the back plate 150 are laminated to form the solar photovoltaic module 100 of FIG. 1. During the heating lamination process, the first packaging material 120′ and the second packaging material 130′ are melted under high temperature and generate fluidity, and therefore are able to cover the solar cell 110 and contact with each other. After the fluid-state first packaging material 120′ and the fluid-state second packaging material 130′ cool down, the first packaging material 120′ and the second packaging material 130′ will respectively be cured as the first package layer 120 and the second package layer 130.

The crosslink density of polyolefin (such as the first package layer 120) and the crosslink density of ethylene vinyl acetate (such as the second package layer 130) used in the embodiment of the invention are within the range of 95.5% to 96.2% and the range of 92.3% to 93.1% respectively, and both are larger than the crosslink density of ordinary epoxy which is smaller than 40%. Therefore, after the lamination process is performed, the first package layer 120 and the second package layer 130 closely contact with each other and tightly cover the solar cell 110.

Under different process conditions, the same materials may have different crosslink densities. The crosslink density of the first package layer 120 and the crosslink density of the second package layer 130 of the embodiment of the invention have a difference of 15% under the same process conditions. Since the difference in crosslink density is small, the first package layer 120 and the second package layer 130 can closely contact with each other. Furthermore, the two opposite sides of the solar cell are covered with homogeneous materials. Since the difference in crosslink density is not large, close coverage and expected weatherability can be achieved. However, the consideration of using homogeneous materials prevents technicians from thinking of covering two opposite sides of the solar cell with heterogeneous materials. On the contrary, even when the two opposite sides of the solar cell 110 are sealed with different packaging layers (heterogeneous packaging), the solar photovoltaic module 100 of embodiment of the invention still can achieve superior coverage and weatherability.

While the invention has been described by way of example and in terms of the preferred embodiment (s), it is to be understood that the invention is not limited thereto. On the contrary, it is intended to cover various modification and similar arrangements and procedures, and the scope of the appended claims therefore should be accorded the broadest interpretation so as to encompass all such modification and similar arrangements and procedures.

1. A solar photovoltaic module, comprising:
a solar cell having a first surface and a second surface opposite to the first surface;
a first package layer formed on the first surface; and
a second package layer forming on the second surface;
wherein, the first package layer and the second package layer are made of different crosslinked materials, and a difference between the crosslink density of the first package layer and the crosslink density of the second package layer is equal to or less than 15%;
wherein the second package layer directly contacts the second surface of the solar cell, and the first package layer and the second package layer directly contact each other.

2. The solar photovoltaic module according to claim 1, wherein the first package layer and the second package layer seal the solar cell.

3. The solar photovoltaic module according to claim 1, wherein the solar cell comprises a plurality of series cell units.

4. The solar photovoltaic module according to claim 1, wherein the first package layer is made of polyolefin or ethylene vinyl acetate (EVA).

5. The solar photovoltaic module according to claim 1, wherein the second package layer is made of polyolefin or ethylene vinyl acetate.

6. The solar photovoltaic module according to claim 1, wherein the first package layer is made of polyolefin, and the second package layer is made of ethylene vinyl acetate.

7. The solar photovoltaic module according to claim 5, wherein the first package layer is formed on the solar light incident surface of the solar photovoltaic module, and the insulation resistance of the first package layer is larger than the insulation resistance of the second package layer.

8. The solar photovoltaic module according to claim 1, wherein the difference between the crosslink density of the first package layer and the crosslink density of the second package layer is measured under the same lamination conditions.
